(19) United States
(12) Patent Application Publication
(10) Pub. No.: US 2015/0075602 A1
(43) Pub. Date: Mar. 19, 2015

(54) PHOTOVOLTAIC CELL WITH GRAPHENE-FERROELECTRIC ELECTRODE

(71) Applicant: National University Of Singapore, Singapore (SG)

(72) Inventors: Barbaros Ozyilmaz, Singapore (SG); Surajit Saha, Singapore (SG); Chee Tat Toh, Singapore (SG); Orhan Kahya, Singapore (SG); Guang Xi Ni, Singapore (SG)

(21) Appl. No.: 14/385,680

(22) PCT Filed: Mar. 22, 2013
(86) PCT No.: PCT/SG2013/000114

§ 371 Date: Sep. 16, 2014

Related U.S. Application Data
(60) Provisional application No. 61/614,655, filed on Mar. 23, 2012.

(51) Int. Cl. H01L 31/0224; H01L 51/00; H01L 51/44

(52) U.S. Cl. CPC H01L 31/022466; H01L 31/022425; H01L 51/442; H01L 51/0036
USPC 136/256

(57) ABSTRACT

A photovoltaic cell (10) is disclosed that includes an active layer (20) sandwiched by top and bottom graphene-ferroelectric electrodes (30T, 30B) each having a graphene layer (32) and a polarized ferroelectric layer (34). The polarized ferroelectric layer defines an internal electric field (EI). Light (50) irradiates the active layer through the top graphene-ferroelectric electrode, causing the generation in the active layer of electrons (e) and holes (h) as charge carriers. The internal electric field causes the electrons and holes to move towards opposite electrodes, giving rise to a photocurrent (ipc), while also mitigating undesirable charge-carrier recombination.

### CLAIM OF PRIORITY

This Application claims the benefit of priority of U.S. Provisional Patent Application Ser. No. 61/614,655, entitled “Photovoltaic Cell Based on Graphene Ferroelectric Interface and the Method of Fabrication Thereof,” filed on Mar. 23, 2012, and which is incorporated by reference herein.

### FIELD

The present disclosure relates to photovoltaic cells, and in particular relates to a photovoltaic cell with at least one graphene-ferroelectric electrode, and methods of forming the photovoltaic cell.

### BACKGROUND

Photovoltaic cells (or solar cells) are devices that convert light into electricity. A typical photovoltaic cell includes a material that can absorb light and generate charge carriers in the form of electrons and holes. Conductive contacts are used to support an electric potential that causes the separation of the charge carriers to create a photocurrent.

Most photovoltaic cells utilize a semiconductor material, such as silicon. While semiconductor-based photovoltaic cells are relatively efficient, they are also expensive. Attention has thus been directed to employing organic photopolymers in place of the semiconductor material. While less efficient, the organic photopolymers are much less expensive, and can also be used to make flexible photovoltaic cells. The organic photopolymer is configured in a matrix that includes electron donor and electron acceptor materials. Thus, while the organic polymer matrix does not include a p/n junction per se like a true semiconductor, the matrix includes interfaces that allow for the dissociation of excitons in a manner similar to a semiconductor-based p/n junction. In this sense, organic polymers act as pseudo-semiconductors.

As with photovoltaic cells based on conventional semiconductors, photovoltaic cells based on organic polymers suffer from reduced conversion efficiency due to the recombination of electrons and holes (i.e., exciton recombination), which reduces the amount of electricity produced.

This charge-carrier recombination is the main cause of energy loss in organic polymer photovoltaic cells and limits their efficiency. It has been shown that in such photovoltaic cells, more than 50% of the energy loss is due to this non-radiative recombination process. Moreover, organic-based photovoltaic cells typically employ rigid and fragile electrodes like ITO/Ag/Al, which limit their applications in many sectors, including flexible devices.

### SUMMARY

An aspect of the disclosure is a photovoltaic cell device for generating a photocurrent when irradiated with light. The device includes an active layer having top and bottom surfaces and that generates charge carriers when irradiated with the light. The device also includes top and bottom electrodes respectively interfaced with the top and bottom layers of the active layer. The top electrode comprises a first graphene layer and a first polarized ferroelectric layer. The first polarized ferroelectric layer defines an internal electric field that extends into the active layer and that facilitates the generation of the photocurrent.

Another aspect of the disclosure is the photovoltaic cell device as described above, wherein the first graphene layer includes either two-dimensional (2D) graphene or three-dimensional (3D) graphene.

Another aspect of the disclosure is the photovoltaic cell device as described above, wherein the first polarized ferroelectric layer comprises a ferroelectric polymer.

Another aspect of the disclosure is the photovoltaic cell device as described above, wherein the ferroelectric polymer comprises P(VDF-TrFE).

Another aspect of the disclosure is the photovoltaic cell device as described above, wherein the active layer comprises one of: silicon, an organic semiconducting polymer, dye-sensitized molecules, gallium arsenide, cadmium telluride, and copper indium gallium selenide.

Another aspect of the disclosure is the photovoltaic cell device as described above, wherein the organic semiconducting polymer is P3HT:PC₇₀BM.

Another aspect of the disclosure is the photovoltaic cell device as described above, wherein the bottom electrode comprises either a metal electrode or a second graphene layer and a second polarized ferroelectric layer.

Another aspect of the disclosure is the photovoltaic cell device as described above, wherein the first graphene layer resides between the first polarized ferroelectric layer and the active layer.

Another aspect of the disclosure is the photovoltaic cell device as described above, wherein the top electrode further includes a conductive layer on the first polarized ferroelectric layer.

Another aspect of the disclosure is the photovoltaic cell device as described above, wherein the first graphene layer comprises doped graphene.

Another aspect of the disclosure is the photovoltaic cell device as described above, wherein the first graphene layer has a select work function that is defined by the first polarized ferroelectric layer.

Another aspect of the disclosure is the photovoltaic cell device as described above, wherein the charge carriers are subject to an amount of charge-carrier recombination, and wherein the internal electric field reduces the amount of charge carrier recombination.

Another aspect of the disclosure a photovoltaic cell device capable of generating a photocurrent. The device includes an active layer comprising an organic semiconducting polymer layer having top and bottom surfaces. The device also includes a top electrode interfaced with the top surface of the active layer. The top electrode comprises a graphene layer and a ferroelectric layer that includes a polarized ferroelectric polymer that generates an internal electric field that extends into the active layer. The active layer generates charge carriers in response to being irradiated with light through the top electrode. The internal electric field reduces an amount of charge-carrier recombination as compared to that in the absence of the internal electric field and serves to generate the photocurrent.

Another aspect of the disclosure is the photovoltaic cell device as described above, wherein the polarized ferroelectric polymer comprises P(VDF-TrFE) and wherein the organic semiconducting polymer layer comprises P3HT:PC₇₀BM.

Another aspect of the disclosure is the photovoltaic cell device as described above, wherein the graphene layer comprises between one sheet and forty sheets of one-atom-thickness graphene.

Another aspect of the disclosure is the photovoltaic cell device as described above, wherein the graphene layer has a select work function that is defined by the polarized ferroelectric polymer of the ferroelectric layer.

Another aspect of the disclosure is a method of generating a photocurrent in a photovoltaic cell having an active layer sandwiched by first and second electrodes. The method includes: illuminating the active layer through the first electrode to generate electrons and holes in the active layer, wherein the first electrode includes a first graphene layer and a first polarized ferroelectric layer; using the first polarized ferroelectric layer, forming a first internal electric field that extends into the active layer; and generating a photocurrent by the first internal electric field causing the electrons and holes to move to opposite ones of the first and second electrodes.

Another aspect of the disclosure is the method described above, wherein the second electrode comprises a second graphene layer and a second polarized ferroelectric layer, and further comprising: the second polarized ferroelectric layer forming a second internal electric field that extends into the active layer, thereby further contributing to the moving of the electrons and holes to opposite ones of the first and second electrodes.

Another aspect of the disclosure is the photovoltaic cell device as described above, wherein the active layer comprises one of: silicon, an organic semiconducting polymer, dye-sensitized molecules, gallium arsenide, cadmium telluride, and copper indium gallium selenide.

Another aspect of the disclosure is the photovoltaic cell device as described above, wherein the first graphene layer has a select work function that is defined by the first polarized ferroelectric layer.

The photovoltaic cells disclosed herein are cost-effective, have high conversion efficiency, can be made flexible, and can be scaled to small and large sizes. The photovoltaic cells disclosed herein have industrial applicability for providing power to a wide range of electrically powered devices such as mobile phones, smart phones, portable computers, cameras, watches, and the like.

### BRIEF DESCRIPTION OF THE DRAWINGS

The accompanying drawings are included to provide a further understanding, and are incorporated in and constitute a part of this specification. The drawings illustrate one or more embodiment(s), and together with the Detailed Description serve to explain principles and operation of the various embodiments. As such, the disclosure will become more fully understood from the following Detailed Description, taken in conjunction with the accompanying Figures, in which:

FIGS. 1A and 1B show main example embodiments of the photovoltaic cell disclosed herein;

FIG. 2A shows an example photovoltaic cell that includes top and bottom graphene-ferroelectric electrodes, wherein the graphene layers resides immediately adjacent to the active layer;

FIG. 2B shows an example photovoltaic cell similar to that of FIG. 2A, but wherein the order of the graphene layer and the ferroelectric layer is reversed in each of the graphene-ferroelectric electrodes;

FIGS. 2C and 2D show example photovoltaic cells similar to that of FIGS. 2A and 2B, but wherein the bottom graphene-ferroelectric electrode is replaced by a conventional electrode;

FIGS. 2E and 2F show example photovoltaic cells similar to that of FIGS. 2C and 2D, but wherein the top graphene ferroelectric electrode includes a conductive layer, which in the example of FIG. 2F is a second graphene layer; and

FIGS. 3A and 3B show example photovoltaic cells similar to those shown in FIGS. 2A, 2B and FIGS. 2C, 2D, respectively, wherein the cell include protective substrates that sandwich the top and bottom electrodes.

### DETAILED DESCRIPTION

Reference is now made in detail to various embodiments of the disclosure, examples of which are illustrated in the accompanying drawings. Whenever possible, the same or like reference numbers and symbols are used throughout the drawings to refer to the same or like parts. The drawings are not necessarily to scale, and one skilled in the art will recognize where the drawings have been simplified to illustrate the key aspects of the disclosure.

The claims as set forth below are incorporated into and constitute part of this Detailed Description.

### General Photovoltaic Cell Embodiments

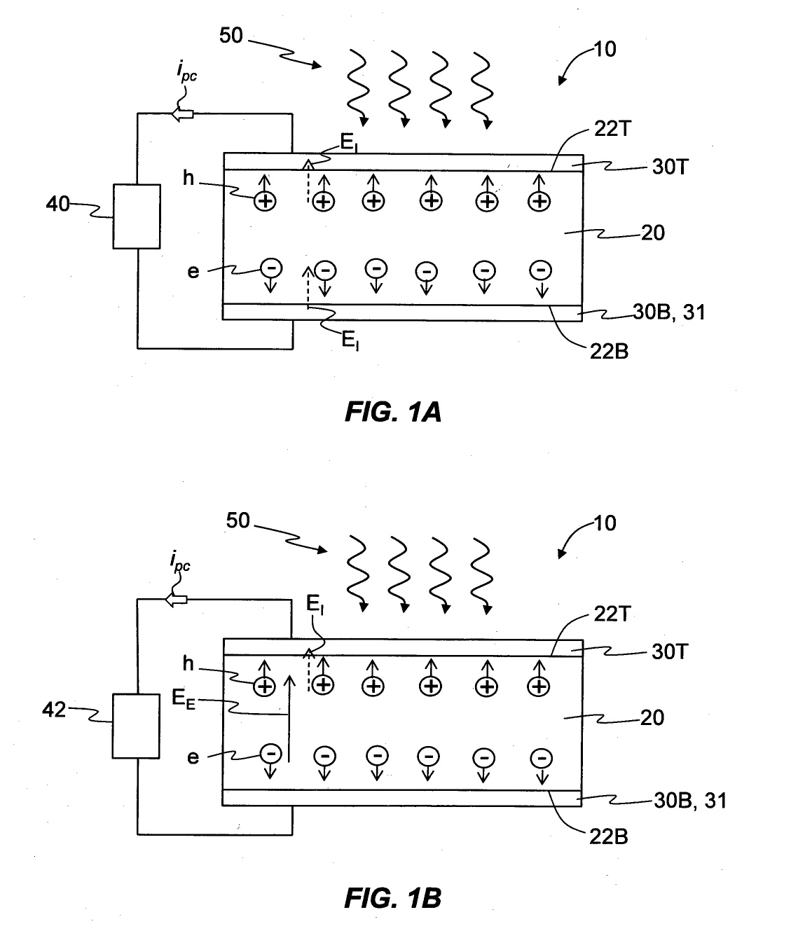

FIGS. 1A and 1B are schematic diagrams that respectively illustrate two main example embodiments of a photovoltaic cell device (“photovoltaic cell”) 10 according to the disclosure. The photovoltaic cell 10 includes an active layer 20 made of one or more materials and that generates photo-induced electrons e and holes h when irradiated with light 50. Active layer 20 has a top surface 22T and a bottom surface 22B. In an example, active layer 20 comprises an organic semiconducting polymer photovoltaic matrix, such as a polymeric blend of P3HT:PC₇₀BM. In another example, active layer 20 comprises silicon. In yet other examples, active layer 20 comprises dye-sensitized molecules, gallium arsenide, cadmium telluride, or copper indium gallium selenide.

Photovoltaic cell 10 also includes top and bottom graphene-ferroelectric electrodes 30, respectively denoted as 30T and 30B. Top and bottom (or “first and second”) graphene-ferroelectric electrodes 30T and 30B are respectively interfaced with the top and bottom surfaces 22T and 22B of active layer 20.

FIG. 1A illustrates an embodiment of photovoltaic cell 10 wherein the photovoltaic cell is electrically connected to a device 40 being powered by photovoltaic cell 10. In this embodiment, device 40 represents a load having an effective load resistance R_{L}.

FIG. 1B illustrates an embodiment wherein photovoltaic cell 10 is electrically connected to a voltage source 42. Such an arrangement can be used when photovoltaic cell 10 is used as a photodetector. Voltage source 42 generates an external electric field E_{E}.

Graphene-ferroelectric electrodes 30T and 30B each give rise to (i.e., define) an internal electric field E_{I} for the reasons discussed below. The direction of internal electric field E_{I} can be selected based on the desired direction of the photocurrent i_{pc}.

Light 50 is shown as being incident on photovoltaic cell 10 at top graphene-ferroelectric electrode 30T, which is substantially transparent to the incident light. Light 50 thus passes through top graphene-ferroelectric electrode 30T to active layer 20, which in response generates excitons, e.g., pairs of electrons e and holes h that are bound by the Coulomb force. A fraction of the excitons will separate into electrons e and holes h, with the internal electric field E_{I} causing the holes h to move toward top graphene-ferroelectric 30T and the electrons e to move toward bottom graphene-ferroelectric 30B. This gives rise to the aforementioned photocurrent i_{pc}, which can be used to operate device 40.

A fraction of the excitons will also undergo recombination and thus will not contribute to the photocurrent i_{pc}. The mitigation of this phenomenon is explained in greater detail below in connection with the advantages of utilizing one or more graphene-ferroelectric electrodes 30 in photovoltaic cell 10.

### Example Graphene-Ferroelectric Electrode Embodiments

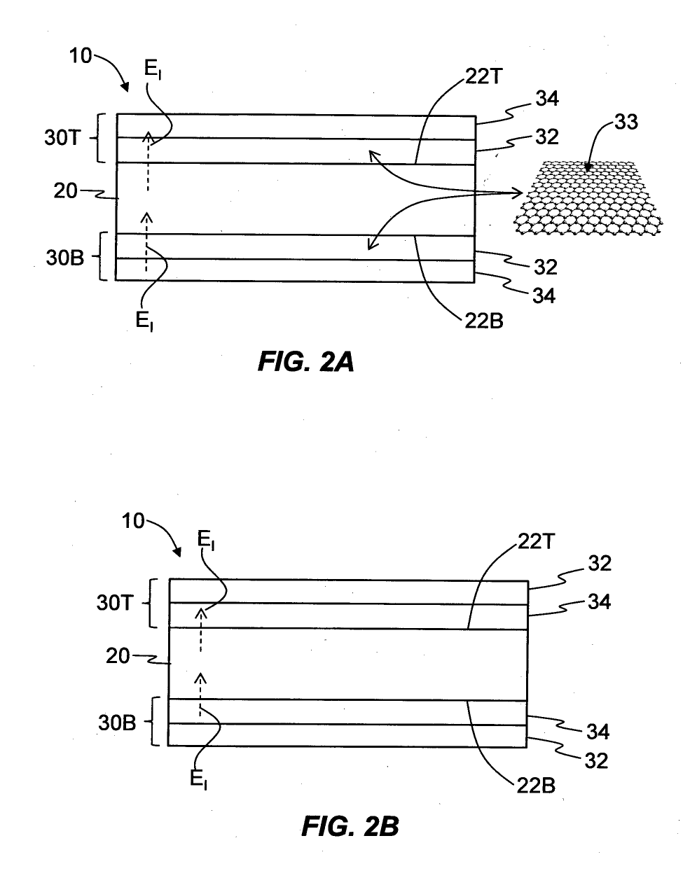

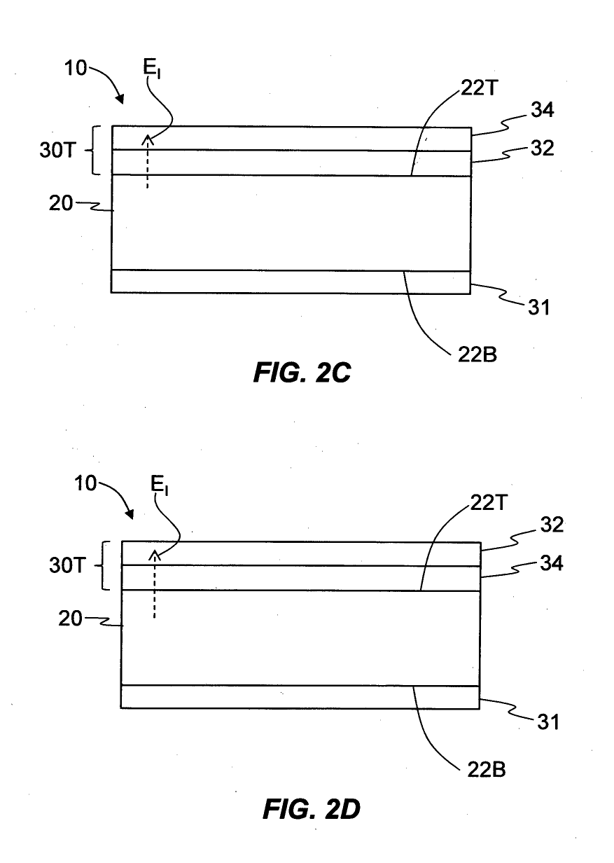

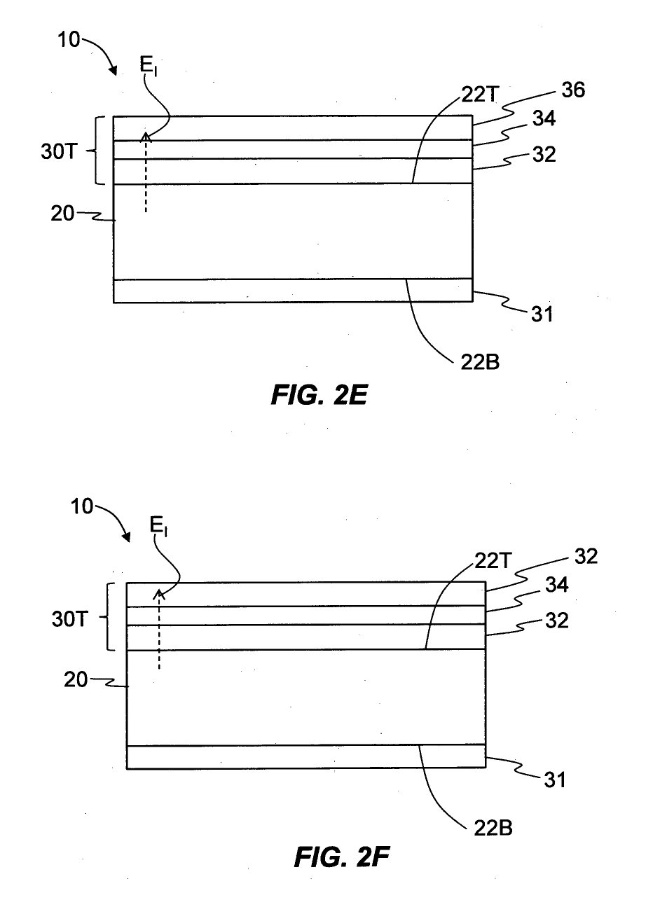

FIG. 2A is a schematic cross-sectional view of an example photovoltaic cell 10 that includes top and bottom graphene-ferroelectric electrodes 30T and 30B. Top graphene-ferroelectric electrode 30T comprises a graphene layer 32 interfaced with the top surface 22T of active layer 20, and a polarized ferroelectric layer 34 interfaced with the graphene layer on the side opposite the active layer. Likewise, bottom graphene-ferroelectric electrode 30B comprises a graphene layer 32 interfaced with the bottom surface 22B of active layer 20, and a polarized ferroelectric layer 34 interfaced with the graphene layer on the side opposite the active layer. In an example, graphene-ferroelectric electrode 30 consists of graphene layer 32 and polarized ferroelectric layer 34.

Graphene layer 32 includes graphene 33 in or more of its available forms, as discussed in greater detail below. Graphene 33 is shown in FIG. 2A as a single sheet (i.e., a one-atomic-layer sheet) by way of example. The internal electric fields E_{I} contributed by top and bottom graphene-ferroelectric electrodes 30T and 30B are also shown by way of example as being oriented towards the top electrode.

FIG. 2B shows an example photovoltaic cell 10 similar to that of FIG. 2A, but wherein the order of graphene layer 32 and the polarized ferroelectric layer 34 is reversed in each of the top and bottom graphene-ferroelectric electrodes 30T and 30B so that the polarized ferroelectric layers are interfaced with active layer 20 and the graphene layers reside on the polarized ferroelectric layers on the side opposite the active layer.

FIG. 2C shows an example photovoltaic cell 10 similar to that of FIG. 2A, but wherein the bottom graphene-ferroelectric electrode 30B is replaced with a conventional bottom electrode 31. Because light 50 is incident upon photovoltaic cell 10 through the top graphene-ferroelectric 30T, the conventional bottom electrode 31 can be opaque.

FIG. 2D is similar to FIG. 2C, but with order of the graphene layer 32 and the polarized ferroelectric layer 34 in the top graphene-ferroelectric electrode reversed so that the polarized ferroelectric layer is interfaced with active layer 20.

FIG. 2E is similar to FIG. 2C, but with a conductive layer 36 formed on polarized ferroelectric layer 34. Conductive layer 36 can be fixed or can be removable. If conductive layer 36 is fixed, it can be made of a substantially transparent material, such as ITO, carbon nanotubes, nanowires, thin films of gold, silver, copper or other metal conductors, etc. Conductive layer 36 is used to polarize the ferroelectric layer 34 by allowing for an electric field to be applied between the conductive layer and graphene layer 32. This electric field can be established by connecting voltage source 42 to conductive layer 36 and graphene layer 32. As noted below, in an example this electric field need only applied for a time sufficient to polarize ferroelectric layer 34, since this layer is capable of remaining polarized in the absence of the electric field. The benefits of having a polarized ferroelectric layer 34 are discussed below.

FIG. 2F is similar to FIG. 2E, except that the conductive layer 36 is formed by a second graphene layer 32. This is possible because graphene is electrically conductive.

### The Graphene Layer

In the various example embodiments of photovoltaic cell 10, graphene layer 32 can have a number of different configurations based on the various available forms for graphene 33. In one example, graphene layer 32 can comprise one or more 2D graphene sheets, while in another example the graphene layer can comprise 3D graphene foam (also called corrugated graphene).

In an example embodiment, graphene layer 32 includes between one and forty layers of graphene 33, with a single layer (i.e., a one-atomic-layer sheet) being about 0.4 nm in thickness (see close-up view of FIG. 2A). In another example, graphene layer 32 when made up of 2D graphene 33 can be up to 15 nm thick. In another example, graphene layer 32 can have from one to four layers of graphene 33. Each single layer of graphene 33 reduces the transparency in the visible (optical) wavelength band by about 2.3%.

In an example embodiment where graphene layer 32 is made up of 3D graphene foam, there can be some mixing between the graphene foam and the ferroelectric material that makes up ferroelectric layer 34. In an example embodiment, graphene layer 32 can have a minimum thickness of about 15 nm when graphene 33 comprises 3D graphene foam.

The work function of graphene can be varied from its nominal value of 4.5 eV by doping. The doping can be accomplished by using atoms (sometimes called “hetero-doping”), by using molecules (sometimes called “chemical modification”) or by using an electric field (sometimes called “electric field tuning”). Thus, in an example, graphene layer 32 comprises graphene 33 that is doped using one or more of these doping mechanisms.

In addition, since graphene is substantially transparent to visible, near-UV and mid-UV wavelengths of light, an example graphene layer 32 is configured to be substantially transparent to these wavelengths of light.

In an example embodiment, the one or more graphene layers (sheets) 33 in graphene layer 32 can be grown as a single film by a chemical vapor deposition (CVD) method. In another example, the one or more graphene layers 33 are formed by a controlled stacking process using a stacking solution that allows for small graphene platelets to be formed into a continuous graphene film.

In another example embodiment, graphene 33 in graphene layer 32 can comprise the aforementioned 3D graphene foam, which is particularly useful in forming highly conductive electrodes. Graphene foam typically has lower transparency (i.e., has greater opacity) than 2D graphene sheets, i.e., its absorption is greater than the 2.3% associated with a single graphene sheet.

Because graphene is impermeable to the diffusion of atoms and molecules therethrough, graphene layer 32 serves as an impermeable layer for photovoltaic cell 10. This reduces the degradation of photovoltaic cell 10 and in particular active layer 20. For example, graphene 33 in graphene layer 32 can prevent metal (e.g., from electrical contacts, not shown) or can prevent a gas (e.g., oxygen from the ambient atmosphere) from reaching the underlying layers, e.g., polarized ferroelectric layer 34 (in some configurations) and active layer 20. This is in contrast to conventional photovoltaic cell interfaces, where the interdiffusion of metal and atoms and molecules over time reduces the photovoltaic cell efficiency. In the specific case of organic-based photovoltaic cells, the organic active layer can be rendered completely nonfunctional if exposed to air. Consequently, the undesirable interdiffusion of atoms and molecules into the organic active region limits the lifespan of the organic photovoltaic cell to days to up to about a year for the best devices.

### The Polarized Ferroelectric Layer

The polarized ferroelectric layer 34 can be organic or inorganic. The polarized ferroelectric layer 34 is in a polarized state so that can give rise to the aforementioned internal electric field E. The polarized ferroelectric layer 34 can be in a polarized state either by virtue of its inherent crystalline order, or by being placed into a polarized state by subjecting the layer to an electric field. The polarized ferroelectric layer 34 can be polarized either prior to being incorporated into photovoltaic cell 10.

The polarized ferroelectric layer 34 can also be polarized during the process used to form the ferroelectric layer as part of forming graphene-ferroelectric electrode 30. The polarized ferroelectric layer 34 can also be polarized after the full photovoltaic cell 10 is created. Once polarized ferroelectric layer 34 is put into its polarized state by an electric field, the electric field need not be maintained. In an example, the polarizing electric field can be periodically applied when needed to re-establish the polarization of polarized ferroelectric layer 34.

An aspect of the disclosure includes tuning the degree of polarization of polarized ferroelectric layer 34 in order to vary the work function for graphene layer 32, and in an example provide (e.g., define) a select value for the work function. This is an example of the aforementioned electric-field-based graphene doping. The polarized ferroelectric layer 34 in the graphene-ferroelectric electrode 30 can be used to dope graphene layer 32 with opposite charge carriers (i.e., electrons e and holes h). The opposite doping induces a difference in the work function of graphene layer 32, thereby introducing an electric field on top of the internal electric field E_{I} from the ferroelectric layer polarization. It is estimated that this can increases the conversion efficiency of photovoltaic cell 10 by 10% to 20%.

In one experiment conducted by the inventors, polarized ferroelectric layer 34 was constituted by a ferroelectric polymer P(VDF-TrFE). This ferroelectric polymer was polarized and the graphene-ferroelectric electrode 30 was formed. A change in the graphene work function of up to +/−0.7 eV was measured relative to the nominal graphene work function of 4.5 eV. Depending on the exact ferroelectric material making up polarized ferroelectric layer 34, the graphene work function can be tuned over an even greater range. Thus, in an example, the graphene work function can be defined by the polarized ferroelectric layer 34 to have a select value other than its nominal value.

In another example embodiment, the graphene work function is changed by changing the composition of the polarized ferroelectric layer 34 to change the amount of polarization this layer can have. For example, where polarized ferroelectric layer 34 comprises a ferroelectric copolymer, the copolymer ratio can be changed. Thus, in an example where polarized ferroelectric layer 34 comprises the copolymer P(VDF-TrFE), the ratio of PVDF to TrFE can be changed to change the maximum polarization of the copolymer, which in turn affects the amount of change in the graphene work function. In another example where polarized ferroelectric layer 34 comprises the inorganic ferroelectric ceramic material PZT (i.e., lead zirconate titanate or (Pb[Zr(x)Ti(1−x)]O3)), changing the ratio of Zr to Ti in the ferroelectric crystal, changes the maximum polarization of the material.

By matching the work function of the top graphene-ferroelectric electrode 30T to that of the interface between this electrode and active layer 20, the conversion efficiency of photovoltaic cell 10 can be optimized.

The internal electric field E_{I} defined by polarized ferroelectric layer 34 can also serve to mitigate the adverse effects on conversion efficiency caused by charge-carrier recombination. The internal electric field E_{I} from polarized ferroelectric layer 34 extends into active layer 20 and so can be felt by the charge carriers residing therein. This internal electric field serves to accelerate the charge carriers to their respective electrodes, e.g., holes h to top graphene-ferroelectric 30T and electrons e to bottom graphene-ferroelectric 30B or 31.

The faster the charge carriers can reach their respective electrodes, the less time they remain within active medium 20, which reduces the rate of charge-carrier recombination. The smaller the rate of charge-carrier recombination, the greater the conversion efficiency of photovoltaic cell 10. The use of top and bottom graphene-ferroelectric electrodes 30T and 30B contributes two (i.e., first and second) internal electric fields E_{I}, such as shown in FIGS. 2A and 2B. This increases the photocurrent and provides a greater reduction in the charger-carrier combination as compared to using a single graphene-ferroelectric electrode.

A typical polarized ferroelectric layer 34 can give rise to an internal electric field E_{I} of about 50V μm⁻¹. This is nearly ten times larger than that achievable by the use of conventional electrodes. This translates into an improvement in efficiency of photovoltaic cell 10 over conventional organic photovoltaic cells, e.g., from 1% to 2% without layers to 4% to 5% with layers. These enhanced efficiencies are 10% to 20% higher than those achieved by other methods, such as conventional morphology and electrode work-function optimization.

In the example embodiment of photovoltaic cell 10 where polarized ferroelectric layer 34 is spaced apart from active layer 20 by graphene layer 32 (see, e.g., FIG. 2A), an example range of thickness for the polarized ferroelectric layer is between 1 nm and about 100 microns. Other thicknesses can be employed as needed, and this range is only exemplary. The same thickness range can be employed when the polarized ferroelectric layer 34 is sandwiched between graphene layer 32 and active layer 20, noting that thickness on the smaller end of this range may be preferred for enhanced performance of photovoltaic cell 10.

### Fabrication Methods

Photovoltaic cell 10 can be fabricated in a number of different ways. In one example, 2D or 3D graphene 33 for graphene layer 32 is formed by CVD on a metal substrate or a corrugated metal mesh (e.g., copper) that catalyzes its growth. In another example, the aforementioned controlled stacking process is employed to form a graphene film.

An ultra-thin (e.g., 1 nm to 2 nm) layer of ferroelectric polymer (e.g. PVDF-TrFE) is deposited on the graphene layer 32 as the polarized ferroelectric layer 34, thereby forming graphene-ferroelectric electrode 30. The graphene-ferroelectric electrode 30 (i.e., the PVDF-TrFE integrated graphene structure) can then be transferred onto transparent and flexible substrate 38, such as a PET substrate. The resulting structure can be cut to form two graphene-ferroelectric electrodes 30 that can be used as the top and bottom electrodes 30T and 30B.

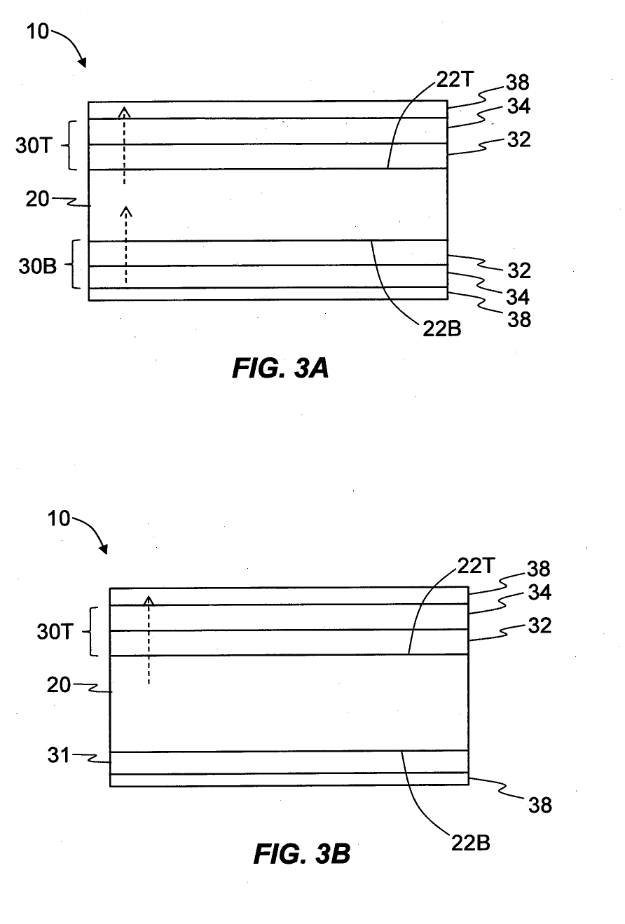

Next, a thin (e.g., about 100-150 nm thick) active layer 20 of organic semiconducting polymer (e.g. P3HT:PC₇₀BM) is deposited on one of the graphene-ferroelectric electrodes 30, say the bottom electrode 30B. Then, the remaining graphene-ferroelectric electrode 30 is interfaced with the active layer 20 supported by bottom electrode 30B so that the organic semiconducting polymer active layer is sandwiched between the two ferroelectric polymer layers of the top and bottom electrodes 30T and 30B. The resulting photovoltaic cell 10 is shown in FIG. 3A and includes the two flexible, thin substrates 38, which serve to protect the device.

At any time along the way in the above process, ferroelectric layer 34 can be polarized by subjecting it to an electric field, such as the external electric field E_{E} as shown in FIG. 1B.

In a variation of the above fabrication method, a conventional bottom electrode 31 can be employed in forming the embodiment of photovoltaic cell 10. FIG. 3B is similar to FIG. 3A and to FIGS. 2C and 2D, and shows an example embodiment of photovoltaic cell 10 formed in such a manner, wherein the bottom electrode is a conventional electrode 31, which is shown as being covered by protective substrate 38.

In another example, the graphene-ferroelectric electrodes 30 formed as described above are transferred onto a corresponding flexible substrate 38, e.g., a PET substrate. A thin active layer 20 in the form of an organic semiconducting polymer matrix is then sandwiched between the two electrode/substrate structures. A potential is then applied across the graphene-ferroelectric electrodes 30T and 30B to polarize (pole) the ferroelectric polymer in (polarized) ferroelectric layers 34. This obviates the need to provide an uninterrupted external electric field.

As discussed above, photovoltaic cell 10 can optionally include the aforementioned voltage source 42 (see e.g., FIG. 1B) to periodically provide an external electric field E_{E} to re-polarize the ferroelectric layer(s) 34. In other words, voltage source 42 can provide an interrupted external electric field E_{E} that only needs to be applied occasionally, in contrast to certain conventional photovoltaic cells that require the application of an uninterrupted electric field.

### Additional Advantages

Conventional organic photovoltaic cells use ITO/silver/aluminum electrodes that encase the organic active layer. Upon photo-illumination, the organic active layer generates pairs of electrons and holes. An uninterrupted (i.e., a continuously applied) external electric field is applied to separate the electron-hole pairs to generate the photo-current. This external electric field can be provided by a voltage source configured to establish an electrical potential between the top and bottom electrodes. The external electric field can also be established by the different layers having different work functions.

An advantage of photovoltaic cell 10 is that it does not require an external electric field E_{E} or an internal electric field E_{I} generated by a difference in work functions to facilitate the separation of the charge carriers. Instead, the internal electric field(s) E_{I} from one or more polarized ferroelectric layers 34 in the one or more graphene-ferroelectric electrodes 30 serves this function. The ability of photovoltaic cell 10 to function without the need for such electric fields provides greater flexibility in how the photovoltaic cell 10 can be deployed and used in a host of applications.

In an example, polarized ferroelectric layer 34 is substantially transparent to near-UV and mid-UV wavelengths. An example material for such a transparent polarized ferroelectric layer 34 is the aforementioned ferroelectric polymer, P(VDF-TrFE). It is noted that ITO is substantially opaque at near-UV and mid-UV wavelengths. Thus, when transparent polarized ferroelectric layer 34 is combined with transparent graphene layer 32, the composite graphene-ferroelectric electrode 30 is also substantially transparent to light 50 over this UV-wavelength range. Thus, graphene-ferroelectric electrode 30 can be used in place of ITO for photovoltaic cells that need to be operational at UV wavelengths.

A conventional organic photovoltaic cell has a high series resistance at the interfaces between the organic and inorganic layers. The use of ITO as the transparent electrode gives rise to this high series resistance. A metal is often used for the other electrode, so that this second interface also has a high series resistance. In contrast, photovoltaic cell 10 as disclosed herein utilizes one or more graphene-ferroelectric electrodes 30, with each having graphene layer 32. As graphene is an organic material, the series resistance at the interfaces between the active layer 20 and the graphene-ferroelectric electrodes 30 is significantly reduced as compared to the conventional configurations, thereby resulting in a much higher conversion efficiency. If polarized ferroelectric layer 34 resides between active layer 20 and graphene layer 32, the use of an organic ferroelectric layer (e.g., an organic polymer) will provide a relatively low series resistance.

Graphene-ferroelectric electrode 30 can also be flexible, so that when used with a flexible active layer 20 (e.g., an organic thin film), photovoltaic cell 10 can be flexible. Moreover, the flexible photovoltaic cell 10 is expected to have a greater conversion efficiency than conventional flexible organic photovoltaic cells. An example flexible graphene-ferroelectric electrode 30 employs a ferroelectric polymer film for polarized ferroelectric layer 34.

What is claimed is:

1. A photovoltaic cell device for generating a photocurrent when irradiated with light, comprising:
an active layer having top and bottom surfaces and that generates charge carriers when irradiated with the light;
top and bottom electrodes respectively interfaced with the top and bottom layers of the active layer; and
wherein the top electrode comprises a first graphene layer and a first polarized ferroelectric layer, wherein the first polarized ferroelectric layer defines an internal electric field that extends into the active layer and that facilitates the generation of the photocurrent.

2. The photovoltaic cell device according to claim 1, wherein the first graphene layer includes either two-dimensional (2D) graphene or three-dimensional (3D) graphene.

3. The photovoltaic cell device according to claim 2, wherein the first polarized ferroelectric layer comprises a ferroelectric polymer.

4. The photovoltaic cell device according to claim 3, wherein the ferroelectric polymer comprises P(VDF-TrFE).

5. The photovoltaic cell device according to claim 1, wherein the active layer comprises one of: silicon, an organic semiconducting polymer, dye-sensitized molecules, gallium arsenide, cadmium telluride, and copper indium gallium selenide.

6. The photovoltaic cell device according to claim 5, wherein the organic semiconducting polymer is P3HT:PC₇₀BM.

7. The photovoltaic cell device according to claim 1, wherein the bottom electrode comprises either a metal electrode or a second graphene layer and a second polarized ferroelectric layer.

8. The photovoltaic cell device according to claim 1, wherein the first graphene layer resides between the first polarized ferroelectric layer and the active layer.

9. The photovoltaic cell device of claim 1, wherein the top electrode further includes a conductive layer on the first polarized ferroelectric layer.

10. The photovoltaic cell device of claim 1, wherein the first graphene layer comprises doped graphene.

11. The photovoltaic cell of claim 1, wherein the first graphene layer has a select work function that is defined by the first polarized ferroelectric layer.

12. The method of claim 1, wherein the charge carriers are subject to an amount of charge-carrier recombination, and wherein the internal electric field reduces the amount of charge carrier recombination.

13. A photovoltaic cell device capable of generating a photocurrent, comprising:
an active layer comprising an organic semiconducting polymer layer having top and bottom surfaces;
a top electrode interfaced with the top surface of the active layer, the top electrode comprising a graphene layer and a ferroelectric layer that includes a polarized ferroelectric polymer that generates an internal electric field that extends into the active layer; and
wherein the active layer generates charge carriers in response to being irradiated with light through the top electrode, and wherein the internal electric field reduces an amount of charge-carrier recombination as compared to that in the absence of the internal electric field and serves to generate the photocurrent.

14. The photovoltaic cell device according to claim 13, wherein the polarized ferroelectric polymer comprises P(VDF-TrFE) and wherein the organic semiconducting polymer layer comprises P3HT:PC₇₀BM.

15. The photovoltaic cell device according to claim 13, wherein the graphene layer comprises between one sheet and forty sheets of one-atom-thickness graphene.

16. The photovoltaic cell device according to claim 13, wherein the graphene layer has a select work function that is defined by the polarized ferroelectric polymer of the ferroelectric layer.

17. A method of generating a photocurrent in a photovoltaic cell having an active layer sandwiched by first and second electrodes, comprising:
illuminating the active layer through the first electrode to generate electrons and holes in the active layer, wherein the first electrode includes a first graphene layer and a first polarized ferroelectric layer;
using the first polarized ferroelectric layer, forming a first internal electric field that extends into the active layer; and
generating a photocurrent by the first internal electric field causing the electrons and holes to move to opposite ones of the first and second electrodes.

18. The method of claim 17, wherein the second electrode comprises a second graphene layer and a second polarized ferroelectric layer, and further comprising:
the second polarized ferroelectric layer forming a second internal electric field that extends into the active layer, thereby further contributing to the moving of the electrons and holes to opposite ones of the first and second electrodes.

19. The method of claim 17, wherein the active layer comprises one of: silicon, an organic semiconducting polymer, dye-sensitized molecules, gallium arsenide, cadmium telluride, and copper indium gallium selenide.

20. The method of claim 17, wherein the first graphene layer has a select work function that is defined by the first polarized ferroelectric layer.
